(19) United States
(12) Patent Application Publication
(10) Pub. No.: US 2025/0227867 A1
(43) Pub. Date: Jul. 10, 2025

(54) INGRESS PROTECTION OF POWER ELECTRONIC DEVICES AND A METHOD FOR AN AIR LEAKAGE TEST THEREOF

(71) Applicant: DANA TM4 ITALIA S.R.L., Arzignano (IT)

(72) Inventors: Walter FAEDO, Vestenanova (IT); Mirko SGAGGIO, Vestenanova (IT); Pierpaolo ZULPO, Arzignano (IT)

(21) Appl. No.: 19/000,222

(22) Filed: Dec. 23, 2024

Related U.S. Application Data
(60) Provisional application No. 63/618,048, filed on Jan. 5, 2024.

(51) Int. Cl. H05K 5/06; G01M 3/32

(52) U.S. Cl. CPC H05K 5/065; G01M 3/3209; H05K 5/069

(57) ABSTRACT

Systems and methods for a case for a power electronics device is provided herein. In one example, a method for manufacturing a case for a power electronics device includes molding the case using a first material, wherein the molding comprises molding a plurality of interconnected channels extending across a surface of the case and around a plurality of power terminal apertures of the case, and injecting a second material into the plurality of interconnected channels to form a continuous seal.

### RELATED APPLICATIONS

The present application claims priority to U.S. Provisional Application No. 63/618,048, entitled “INGRESS PROTECTION OF POWER ELECTRONIC DEVICES AND A METHOD FOR AN AIR LEAKAGE TEST THEREOF,” and filed Jan. 5, 2024, the entire contents of which are hereby incorporated by reference for all purposes.

### TECHNICAL FIELD

The present disclosure relates to a power electronics device, and more specifically to ingress protection of the power electronics device.

### BACKGROUND AND SUMMARY

Power electronics may be sensitive to the environment; small amounts of dust or water interacting with a power electronics device can cause degradation of the power electronics device. This is especially true of power electronics devices that make use of high input or output currents such as converters and inverters. The protection of such devices against the ingress of dust and water can be rated on a scale provided by the international electrotechnical commission (IEC). Power converters and inverters may utilize the highest levels of protection, IEC67 or IEC68, which require a device to be protected from the ingress of dust and protected against water submersion. This may be accomplished by a well-sealed case that surrounds the device on three sides and is fastened to a base plate. The case may be made of plastic or metal and the base plate may be made of metal so that it may act as a heat sink for the device.

Some power electronics devices may include elements that extend outside of the case of the power electronics device. For example, a power electronics device may include power terminals that extend from the interior of the power electronics device to the exterior through a power terminal hole in the case. The power terminals may be made out of a conducting material, which allows power sources or loads connected to the terminals on the exterior of the device to be in electrical contact with power electronics on the inside of the device. These power terminals may include a threaded hole in the center of the exterior face of the power terminal that allows external cables to be bolted into the power terminals. To maintain protection against ingress of dust and water, the power terminals also may be sealed so that no dust or water can enter the interior space of the case through the space between the power terminal and the case. Additionally, the interface between the case and the base plate may be sealed to provide ingress protection.

Previous attempts to create a seal between the power terminal and the case have involved a rubber O-ring. For example, a power terminal may be machined to create a slot around the circumference of a bolt to be inserted in the power terminal. The O-ring may be placed manually into the slot. To create a seal between the case and the base plate, a gasket may be inserted into a slot on the bottom surface of the case in face sharing contact with the base plate. This gasket may close the gap between the case and the baseplate to prevent the ingress of water and dust.

The inventors have identified several drawbacks to this solution. Placing the O-rings by hand may require more time and labor and creates the possibility for one or more of the O-rings to be placed incorrectly. This may lead to an incomplete seal around a power terminal which could allow the ingress of water or dust into the power electronics device. Additionally, each O-ring may be placed by hand on each power terminal and the gasket used to seal the case to the baseplate may be placed separately, which further increases the amount of time it takes to manufacture the item.

The inventors have recognized the aforementioned challenges and developed a method for manufacturing a case for a power electronics device to overcome these challenges. In one example, the method includes molding the case using a first material, wherein the molding comprises molding a plurality of interconnected channels extending across a surface of the case and around a plurality of power terminal apertures of the case, and injecting a second material into the plurality of interconnected channels to form a continuous seal. In this way, the plurality of interconnected channels may allow the second material to form a continuous seal that provides sealing around each power terminal as well as along the sealing interface with the base plate (e.g., where a gasket would conventionally be placed) in the process of one injection. The method according to the disclosure does not demand any aspects of the seal to be placed by hand, which reduces the risk of a mis-positioned seal while also reducing the amount of time it takes to manufacture the case.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE FIGURES

FIG. 1 is an exterior view of an example inverter including a case.

FIG. 2A is a bottom view of a case for an inverter according to embodiments of the disclosure.

FIG. 2B is a bottom perspective view of the case of FIG. 2A.

FIG. 3 is cross-sectional view of a power terminal and over-molded seal of the case of FIGS. 2A and 2B.

FIG. 4A is a magnified cross-sectional view of a power terminal seal of the case of FIGS. 2A and 2B.

FIG. 4B is a magnified exterior view of a power terminal and seal of the case of FIGS. 2A and 2B.

FIG. 5 is a cross sectional view of a power terminal of the case of FIGS. 2A and 2B with a test channel for performing an air leakage test.

FIG. 6 is an exterior view of the case of FIGS. 2A and 2B integrated in an inverter and a device for performing an air leakage test.

FIG. 7 is a graph of air pressure inside the case of FIG. 6 over time during an air leakage test.

FIG. 8 is a diagram of a cable lug connection to a power terminal of an inverter.

FIG. 9 is a cross sectional view of a power terminal of an inverter with a bolt inserted therein.

FIG. 10 is a cross sectional view of a power terminal of an inverter with a valve for closing a test channel.

FIG. 11 is a flowchart a method for manufacturing and performing an air leakage test of an inverter case with an over molded seal.

### DETAILED DESCRIPTION

Embodiments for protecting a power electronics device from the ingress of dust, water and other objects is described below. Ingress protection may prevent some forms of degradation to power electronics and is especially vital for power electronics devices operating in harsh conditions, such as power electronics devices installed in vehicles operating in dusty or wet environments. The disclosed embodiments for ingress protection include the manufacture and testing of an outer case for a power electronics device. The outer case may include holes through which power terminals may extend from the interior to the exterior of the case. The interior portion of each power terminal may contact power electronics inside the case and the exterior portion of each power terminal may contact exterior power sources and loads. The case may be positioned upon a metallic baseplate that can act as a heat sink. To ensure ingress protection, the case may be tightly sealed to the baseplate and around the power terminals via a continuous, over-molded seal. In some examples, the case may first be formed (e.g., molded) out of a first material like hard plastic. The case may include a plurality of interconnected channels, including a channel in a bottom surface of the case (e.g., configured to be in face-sharing contact with the baseplate), channels around the power terminal holes in the case, and channels coupled to the channels in the bottom surface and around the power terminal holes. A second material, like rubber, may then be injected into the plurality of interconnected channels. The plurality of interconnected channels allows the second material to be distributed to all parts of the case that include sealing structures, such as around the power terminal holes and the bottom surface of the case.

Once the case is formed and incorporated in a power electronics device such as an inverter, the case may be tested for air-tightness using an in-line air leakage test that is described herein. This test may asses the sealing state of the case. If the case is air tight, the seals may be functioning, if the case leaks, the seals may not be functioning as intended. The air leakage test may include injecting air into the sealed casing through a test channel in a power terminal of the case and measuring the rate of change of the air pressure, or the pressure decay, in the sealed casing through the test channel over time. The air leakage test can be adapted to cases that may or may not include a vent in the casing. After the air leakage test, the test channel in the power terminal may be sealed by the insertion of a bolt in the power terminal. In some examples, additional mechanisms for sealing the channel may be included as discussed below, such as an over-molded seal or thread locks on the bolt.

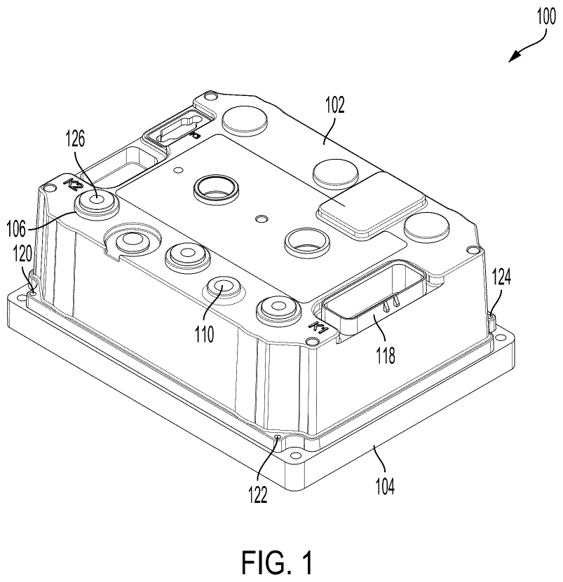

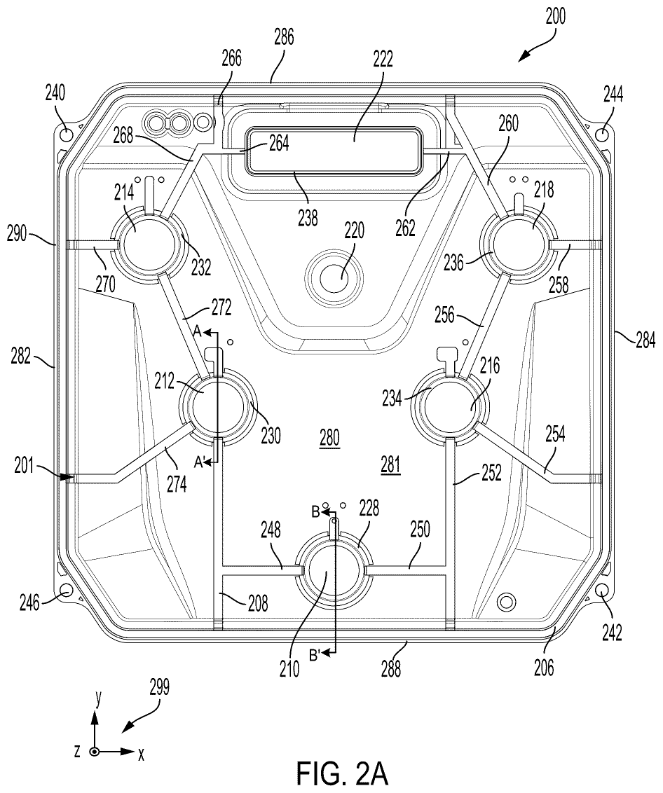

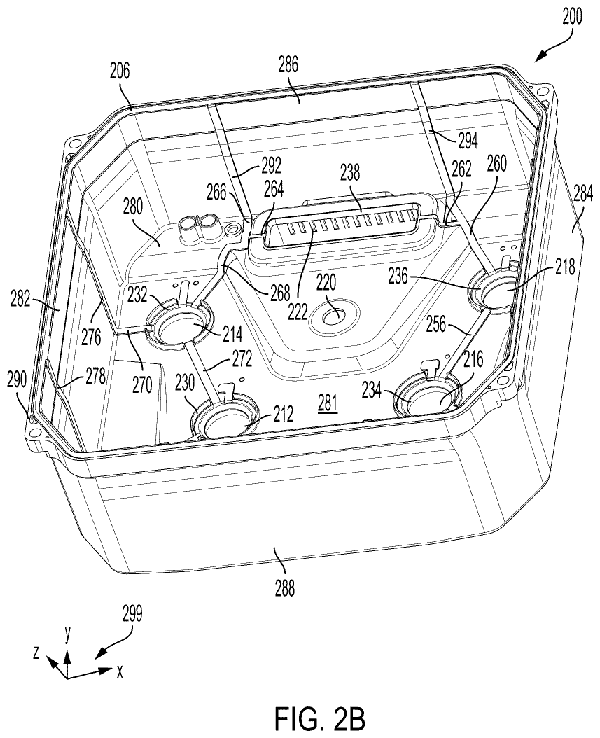

FIGS. 2-6 and 8-10 include a Cartesian coordinate system 299 to orient the views. The coordinate system may be arranged with respect to the position of parts once they are assembled into a power electronics device such as an inverter. The z-axis of coordinate system 299 may be a vertical axis (e.g., parallel to a gravitational axis), the y-axis of coordinate system 299 may be a longitudinal axis (e.g., horizontal axis), and/or the x-axis of coordinate system 299 may be a lateral axis, in one example. However, the axes may have other orientations, in other examples. When referencing direction, positive may refer to in the direction of the arrow of the x-axis, y-axis, and z-axis and negative may refer to in the opposite direction of the arrow of the x-axis, y-axis, and z-axis. A filled circle may represent an arrow and axis facing toward, or positive to, a view. An unfilled circle may represent an arrow and an axis facing away, or negative to, a view. Further, FIGS. 1-6 and 8-10 are drawn to scale, though other relative dimensions could be used if desired.

FIG. 1 depicts an exterior view of an inverter 100 including a case 102 according to the disclosure. An inverter is a non-limiting example of a power electronics device the disclosed case may be employed to protect, though the case and continuous seal described herein may be used in other power electronics devices without departing from the scope of this disclosure, such as power distribution units. The power electronics of the inverter 100 are housed within the case 102, which may be made of a first material, such as rigid plastic. The case 102 may be affixed to a metallic baseplate 104 with fasteners, including a first fastener 120, a second fastener 122, and a third fastener 124. The fasteners may be bolts, screws or other similar fasteners. Only three of these fasteners are visible in FIG. 1, but the inverter 100 may include one or more fasteners at each of the four corners of the case 102. The metallic baseplate 104 may act as a heatsink by conducting heat generated by the power electronics out of the case 102.

The case 102 may include a plurality of holes, also referred to as apertures, such as hole 106, and each hole may accommodate a power terminal, such as power terminal 126. The holes allow the power terminals to extend out of the case 102 and come into contact with external power sources and loads (not shown in FIG. 1). The holes also allow the power terminals to extend within the case 102 and contact interior power electronics. The case 102 may also include a vent cap 110 to allow for air flow between the interior and exterior of the case 102. Additionally, the case 102 may include a port 118 that can be connected to a computing system via a cable with a plug.

FIGS. 2A and 2B show two different views of a case 200 with an over-molded continuous seal. Case 200 may be included in an inverter to enclose power electronics. In this way, case 200 may be a non-limiting example of case 102 of FIG. 1. FIG. 2A is a bottom view that depicts the case from below, while FIG. 2B is a bottom perspective view that depicts the case at a slight angle. FIGS. 2A and 2B are described collectively. The case 200 may be formed out of a first material such as acrylonitrile butadiene styrene (ABS), polymethyl methacrylate (PMMA or acrylic), or another suitable material (e.g., another hard plastic) that may be molded to include various apertures and contours to accommodate the internal power electronics and interfaces with the exterior of the enclosure. The case 200 may include a top 280 whereupon power terminal apertures and vent apertures may be located. The top 280 may be positioned in the x-y plane as defined by coordinate system 299. The case 200 further includes four sides that may be positioned perpendicular to the top 280 along the outer edges of the top 280. A first side 282 is located on the left side of the top 280 and is positioned in the y-z plane as defined by coordinate system 299. A second side 284 is located on the right side of the top 280 and is also positioned in the y-z plane as defined by the coordinate system 299. A third side 286 is positioned on the upper edge of the top 280 relative to the y-axis and is positioned in the x-z plane as defined by coordinate system 299. A fourth side 288 is positioned on the lower edge of the top 280 relative to the y-axis and is also positioned in the x-z plane as defined by coordinate system 299. The casing further includes a bottom circumferential edge 290 that lies in the y-x plane and is comprised of respective bottom edges of the first side 282, the second side 284, the third side 286, and the fourth side 288.

The case 200 may include additional apertures that do not function to accommodate power terminals. For example, a first screw hole 240, a second screw hole 242, a third screw hole 244, and a fourth screw hole 246 may be located at each of the corners of the case 200. These screw holes in the case 200 may allow for screws, bolts, or other fasteners to affix the case to a base plate, such as the metallic baseplate 104 as described above with respect to FIG. 1. The case 200 may be fixed in face-sharing contact with the base plate upon which the power electronics of the inverter may have been assembled.

Other apertures may have their own particular functions. Vent 220 is an aperture that may allow air to pass between the interior of the case and the exterior, which can assist in transferring heat away from the power electronics. A vent cap may be affixed to vent 220 before the manufacturing process is complete to prevent the ingress of dust or water. Case 200 further includes a port aperture 222 that may accommodate a port having I/O pins. The I/O pins may interface with external electronic circuitry and conduct input and output signals. Port aperture 222 may be coupled to a suitable plug when the inverter is in use.

The case 200 may include a first power terminal aperture 210, a second power terminal aperture 212, a third power terminal aperture 214, a fourth power terminal aperture 216, and a fifth power terminal aperture 218 formed in the top 280 of the case and each sized appropriately to accommodate power terminals extending therethrough. The power terminal apertures may be sealed to prevent the ingress of water, dust, and debris between the edges of the top 280 and the power terminals are inserted through the apertures.

The case 200 may be molded with a plurality of interconnected channels formed into an interior surface 281 of the top 280 and the first side 282, the second side 284, the third side 286, and the fourth side 288. The interconnected channels may include channels that surround each power terminal aperture and the port aperture 222, a bottom channel that is formed in bottom circumferential edge 290, and additional channels that couple the surrounding channels to each other. A seal 201 may be formed by injection molding a second (e.g., soft) material like rubber or silicon into the interconnected channels. The seal 201 may protect the device from the ingress of water or dust through the edges or apertures in the case. Seal 201 may be realized by a single injection of soft material, since the interconnected nature of the channels allows the soft material to flow through the entire channel network during injection. Seal 201 can be comprised of various segments to define the functions of different regions of the seal, and all segments of seal 201 are interconnected and form a single seal.

On the interior surface 281 of the top 280 of the case, the seal 201 may include power terminal seals that surround each power terminal aperture. A first power terminal seal 228 surrounds the first power terminal aperture 210, a second power terminal seal 230 surrounds the second power terminal aperture 212, a third power terminal seal 232 surrounds the third power terminal aperture 214, a fourth power terminal seal 234 surrounds the fourth power terminal aperture 216, and a fifth power terminal seal 236 surrounds the fifth power terminal aperture 218. An I/O port seal 238 may surround port aperture 222. The first power terminal seal 228, the second power terminal seal 230, the third power terminal seal 232, the fourth power terminal seal 234, the fifth power terminal seal 236, and the I/O port seal 238 are all connected by seal segments. A first seal segment 248 is coupled to the first power terminal seal 228 and a second seal segment 208. Second seal segment 208 is coupled to second power terminal seal 230. Second power terminal seal 230 is coupled to a third seal segment 274 and a fourth seal segment 272, and fourth seal segment 272 is coupled to the third power terminal seal 232. The third power terminal seal 232 is coupled to a fifth seal segment 270 and a sixth seal segment 268. Sixth seal segment 268 is coupled to a seventh seal segment 266 and an eighth seal segment 264. Eighth seal segment 264 is coupled to I/O port seal 238, which is coupled to ninth seal segment 262. Ninth seal segment 262 is coupled to a tenth seal segment 260, which is coupled to the fifth power terminal seal 236. Fifth power terminal seal 236 is coupled to an eleventh seal segment 258 and a twelfth seal segment 256. Twelfth seal segment 256 is coupled to the fourth power terminal seal 234. Fourth power terminal seal 234 is coupled to a thirteenth seal segment 254 and a fourteenth seal segment 252. Fourteenth seal segment 252 is coupled with a fifteenth seal segment 250, which is coupled to the first power terminal seal 228. First power terminal seal 228 is coupled to the second seal segment 208.

Additional channels formed on the interior surface of the first side 282, the second side 284, the third side 286, and the fourth side 288 may connect the channels on the interior surface of the top 280 of the case to a bottom sealing channel on the bottom circumferential edge 290 of the case. Each of the channels are filled during the injection molding process to produce a portion of the seal 201. Thus, the seal 201 further includes a sealing gasket portion 206 that is located around the perimeter of the case on bottom circumferential edge 290. Sealing gasket portion 206 is connected to the seals/seal segments on the top 280 on the first side 282 by a first vertical seal segment 278 and a second vertical seal segment 276. The first vertical seal segment 278 is coupled with a third seal segment 274 and the second vertical seal segment 276 is coupled with fifth seal segment 270. Sealing gasket portion 206 is connected to seals on the top 280 on the third side 286 by a third vertical seal segment 292 and a fourth vertical seal segment 294. The third vertical seal segment 292 is coupled with a seventh seal segment 266 and the fourth vertical seal segment 294 is coupled with tenth seal segment 260. The interior surface of the second side 284 of the case and fourth side 288 of the case are not visible in FIG. 2A or FIG. 2B. However, channels and seals may be arranged on the second side 284 in a similar fashion to the first side 282 and channels and seals may be arranged on the fourth side in a similar fashion to the third side 286. In this way, all channels on all sides of the case 200 may interconnected and form a continuous seal 201.

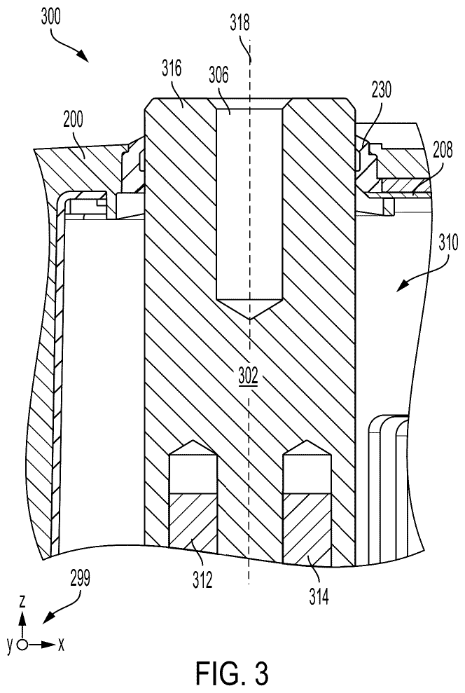

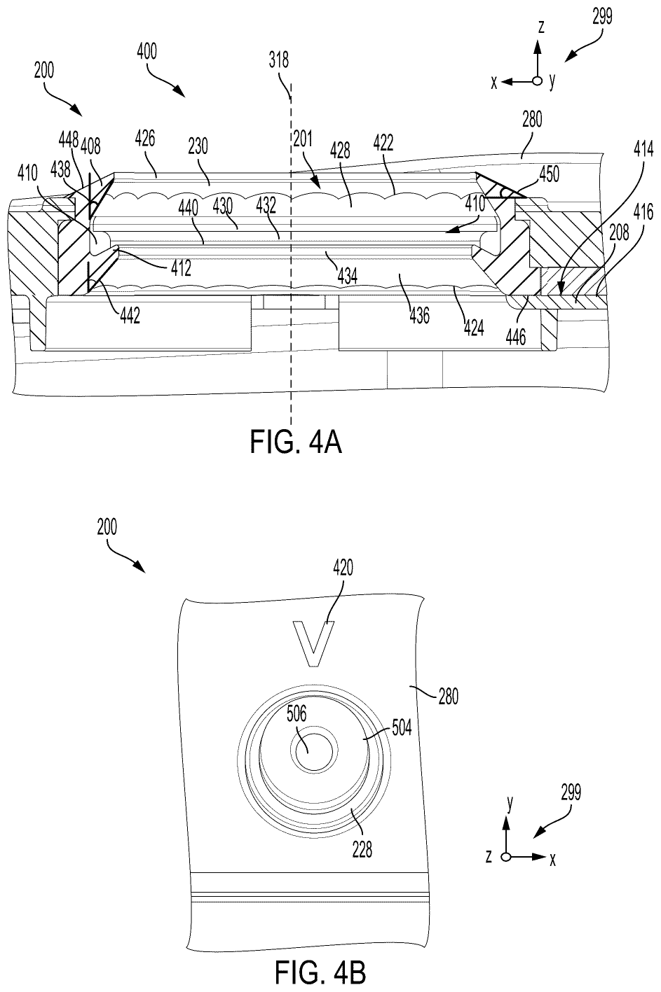

A more detailed look at the power terminals discussed above is shown in FIG. 3. FIG. 3 is a cross sectional view 300 of the case 200 taken across line A-A′ of FIG. 2A after the case has been installed in an inverter and includes components of one of the power terminals extending through the case 200. In particular, FIG. 3 is a cross sectional view 300 of a first power terminal 302 extending through second power terminal aperture 212 in case 200 and surrounded by second power terminal seal 230. The center of the second power terminal aperture 212 is marked by center line 318. The first power terminal 302 may be centered within the second power terminal aperture 212. The first power terminal 302 and the second power terminal seal 230 that surrounds the first power terminal 302 are non-limiting examples of the power terminals extending through the other power terminal apertures in the case 200 and seals surrounding the other power terminal apertures in the case 200. The first power terminal 302 sits within an internal cavity (e.g., an interior space 310) of the case 200. The first power terminal 302 extends vertically through second power terminal aperture 212 in the top 280 of the case 200. An upper face 316 of the first power terminal 302 is in contact with the environment outside of the case 200 and a lower portion of the first power terminal 302 is in contact with interior power electronics, such as first power electronics 312 and second power electronics 314. The first power terminal 302 may include a first inner socket 306 within the first power terminal 302 that extends to a limited depth inside of the first power terminal 302. An external power source or an external load may be affixed to the inverter via a screw, bolt, or another attachment mechanism through the first inner socket 306. Thus, in some examples, the first inner socket 306 may include threads for interfacing with the attachment mechanism and may be referred to as a threaded socket in some examples. The first power terminal 302 may be surrounded by second power terminal seal 230. Second power terminal seal 230 (and likewise the other power terminal seals of the case 200) may have a double lipped shape on the edge of the second power terminal seal 230 that is in contact with the first power terminal 302. The double lipped shape of the power terminal seal may prevent the ingress of dust and water through the interface between the second power terminal seal 230 and the first power terminal 302. The shape of the second power terminal seal 230 is described in more detail with respect to FIG. 4A. The second seal segment 208 is shown coupled with the second power terminal seal 230. As described previously, the second seal segment 208 may connect second power terminal seal 230 to the rest of the seal segments and power terminal seals of the seal 201.

FIG. 4A provides a cross sectional view 400 of the second power terminal seal 230 in the top 280 of case 200 taken across A-A′ of FIG. 2A. The first power terminal 302 is absent to provide a view of the profile of the second power terminal seal 230. The second power terminal seal 230 is circular in shape and center line 318 extends vertically through the center of the second power terminal seal 230. The second power terminal seal 230 is radially symmetric about center line 318. Second power terminal seal 230 is part of the seal 201, as explained previously, and is coupled to the second seal segment 208. The second power terminal seal 230 may be distinguished from the second seal segment 208 by line 446.

A cross section of the second power terminal seal 230 is provided to display a profile of the second power terminal seal 230. The profile of second power terminal seal 230 is shaped to facilitate the insertion of the power terminal parallel to the z axis. The profile may be double-lipped in shape, with a top lip 408 and a bottom lip 412 and an inlet 410 in between top lip 408 and bottom lip 412.

The top lip 408 may have a first edge 426 that is in face sharing contact with the power terminal when the inverter is assembled. A top face 448 of the top lip 408 may extend above the top 280 at an angle 450. Beneath the first edge 426, the top lip may include a first interior face 428 that may recede from the top lip at an acute angle 438 in the x-z plane.

The first interior face 428 may include raised scalloping 422 along its top edge that is in contact with the first edge 426. The first interior face 428 may be coupled to a second interior face 430. The second interior face 430 may lie within inlet 410 and the second interior face 430 may lie parallel to the side of a power terminal inserted into the second power terminal seal 230. The second interior face 430 may include a ridge 432 that extends towards the center line 318. Ridge 432 may include an inlet 440 on the face of ridge 432 that faces the center of the second power terminal seal 230. The bottom of the second interior face 430 may be coupled to the bottom lip 412 of the second power terminal seal 230. The bottom lip 412 may extend upwards at an angle 442 towards the center line 318. The bottom lip 412 may include a second edge 434 that is in face sharing contact with the power terminal when the inverter is assembled. The bottom lip 412 may have a bottom face 436 that is aligned with angle 442. The bottom face 436 may include raised scalloping 424 along its bottom edge.

The double-lipped profile of second power terminal seal 230 (and the remaining power terminal seals of case 200) may facilitate ingress-protected contact between the second power terminal seal 230 and the power terminal inserted in the corresponding aperture once the inverter is fully assembled. The raised scalloping along the first interior face and the bottom face may further improve ingress protection by increasing the frictional force between the seal and the power terminal. The increased frictional force may make the power terminal resistant to slipping out of contact with the seal, which could cause leakage. One or more molds may be used during the injection molding process to form the double lipped shape of the second power terminal seal 230, which includes the top lip 408, the bottom lip 412 and the inlet 410. The second material, in liquid form, may flow into cavities within the mold(s) during injection. Once the second material has cured, the mold(s) may be removed.

FIG. 4A also shows the second seal segment 208, which connects the second power terminal seal 230 to other seal segments within the seal 201. The second seal segment 208 is located in a channel 414 of the plurality of interconnected channels. Channel 414 may be defined by three channel surfaces, including top surface 416 and two side channel surfaces (not shown in FIG. 4A). In some examples, top surface 416 may be a portion of the interior surface 281 of the case 200.

FIG. 4B shows a top view of a power terminal 504 surrounded by the first power terminal seal 228 from the outside of the case 200. The power terminal 504 is encircled by the first power terminal seal 228, which as explained above may be manufactured via injection molding the second material into the plurality of interconnected channels within the case 200. The second material may have a color that contrasts with the color of the case 200 and thus may additionally be used to create text on the exterior surface of the case 200 by integrating text-shaped apertures in the case 200. In FIG. 4B, a V-shaped aperture is included in the case 200 to thereby form a by V-seal 420. V-seal 420 may be produced during the same injection molding process as seal 201 and may be coupled to seal 201. Power terminal 504 has a threaded socket, hereafter referred to as a second inner socket 506, in the center of power terminal 504. The second inner socket 506 can be used to affix external power sources and loads to the device.

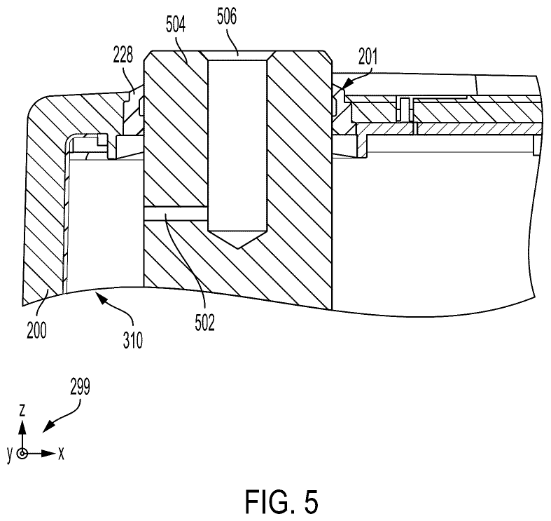

The continuous seal 201 described above may be tested for air leakage during the manufacturing process via a test channel provided in one of the power terminals. FIG. 5 depicts a cross-sectional view (e.g., taken across line B-B′ of FIG. 2A) of power terminal 504 installed in the first power terminal aperture 210 of the case 200. The power terminal 504 may be sealed by the first power terminal seal 228 as described above. The power terminal 504 includes the second inner socket 506 in the center to allow for external cables to be bolted or screwed into place. A test channel 502 in the power terminal fluidly couples the second inner socket 506 to the interior space 310 of the case 200. Prior to installation of a bolt in the second inner socket 506, the test channel 502 may allow air to pass from the environment outside of the case to the interior space 310 through the second inner socket 506.

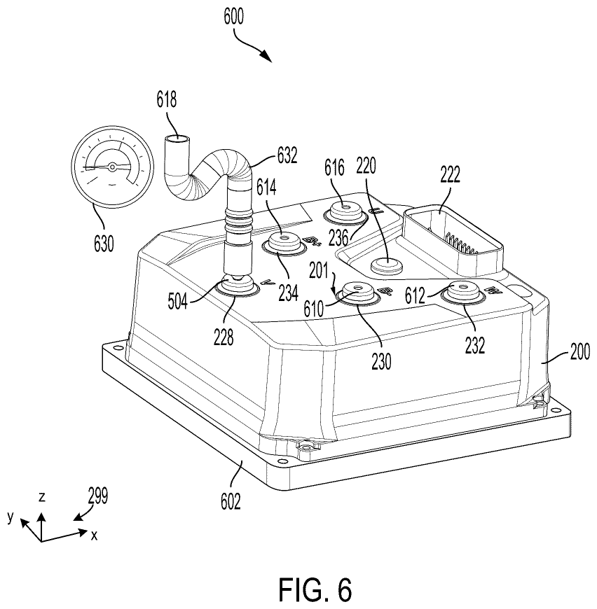

In FIG. 6, an inverter 600 is shown undergoing a leakage test, capable of assessing the sealing state of the case. The inverter 600 includes the case 200 coupled to a base plate 602. As explained above, the case 200 may include vent 220 that allows air to flow out of the case 200. In some examples, the vent 220 may have a cap on it to prevent the ingress of water or dust. As explained previously, case 200 may further include port aperture 222 to connect the inverter 600 to an external computing system via I/O pins. Finally, the top face of the case 200 may have a number of power terminals each surrounded a respective power terminal seal. In this case, power terminal 504, a second power terminal 610, a third power terminal 612, a fourth power terminal 614, and a fifth power terminal 616 are encircled by the first power terminal seal 228, the second power terminal seal 230, the third power terminal seal 232, the fourth power terminal seal 234, and the fifth power terminal seal 236 respectively. As explained with respect to FIG. 5, power terminal 504 includes a test channel extending from the threaded socket of the power terminal to the internal cavity of the case. To perform the leakage test, a tube 632 connected to an air compressor may be inserted into the power terminal 504 (e.g., into the second inner socket 506). The insertion end of the tube may have a nozzle configured to fit snugly against the power terminal 504. Air from the compressor may pass through an inlet 618 of the tube 632 before entering the threaded socket of power terminal 504, passing through the test channel and into the interior space of the case 200. A pressure gauge 630 may be coupled to the tube 632 and employed to determine the pressure inside the case. To perform the leak test, the air compressor may be used to pressurize the interior of the case 200 via the test channel to a predetermined pressure as measured by the pressure gauge. After a predetermined amount of time has passed, the pressure inside the case may be measured again, and the change in pressure between the two times may be used to determine the rate of leakage. The determined rate of leakage, or the pressure decay rate, can be compared to the rate of leakage for a tightly sealed case to assess the sealing state of the case, e.g., to determine if the case being tested is leaking.

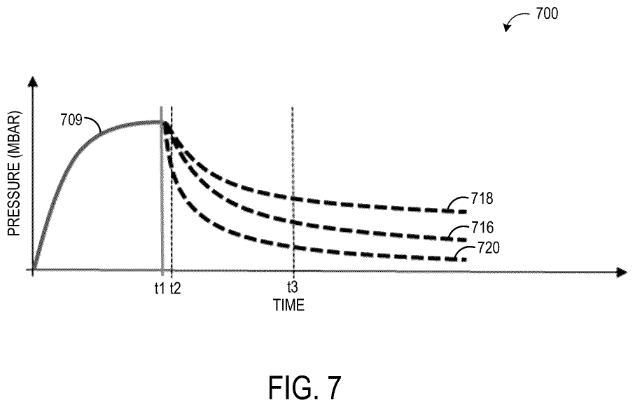

This process is visualized by a graph 700 in FIG. 7. In the graph 700 the x-axis represents the time in seconds that has passed since the air compressor began pumping air into the housing through the power terminal. The y-axis represents the relative pressure inside the case in millibar, where the pressure before the air compressor begins pressurizing the case is represented by zero. Time points of interest are indicated via the vertical lines. The graph is separated into two phases: filling the device and measuring the pressure drop. Phase 1 is filling the device and occurs prior to time t1. During this phase, air may be pumped into the case through a test channel in a power terminal, such as test channel 502 in power terminal 504, as explained above. The increasing pressure during this phase is represented by a line 709. Once the pressure inside the housing has reached a predetermined threshold pressure, the air compressor may be shut off at time t1, and the pressure in the housing may begin to decrease due to the air escaping through a vent, such as the vent 220. As soon as the air compressor is shut off, the second phase of the process begins; phase 2 is measuring the pressure drop. When the air compressor is shut off or shortly thereafter, the pressure inside the housing may be measured for the first time at time t2. After a set amount of time has passed, the pressure in the housing may be measured again at time t3.

Three different pressure change scenarios are displayed on the graph 700. A first pressure change scenario is shown by line 716 and includes the pressure inside the housing decaying at a rate consistent with a fully sealed housing and air leaking out of the housing only through the vent. The first pressure change scenario indicates that the inverter was manufactured with an operable continuous seal and is protected against the ingress of dust or water. A second pressure change scenario is show by line 718 and includes the change in the pressure calculated between the two measurement points being less than the change calculated for the first pressure change scenario/line 716. In the second pressure change scenario, air is not escaping out of the case as fast as expected, which may be due to a clogged vent cap, which would block the release of air. In a third pressure change scenario, represented on the graph by a line 720, air is escaping from the case faster than the first pressure change scenario/line 716. In the third pressure change scenario, the change in air pressure between t2 and t3 is greater than expected. This may be due to a leak in the case, allowing air to escape through a location other than the vent cap. Leaks may occur due to manufacture issues with the continuous seal, such as if the sealing gasket portion between the case and the base plate is degraded, or if any of the power terminal seals in the case are not in tight contact with the power terminals.

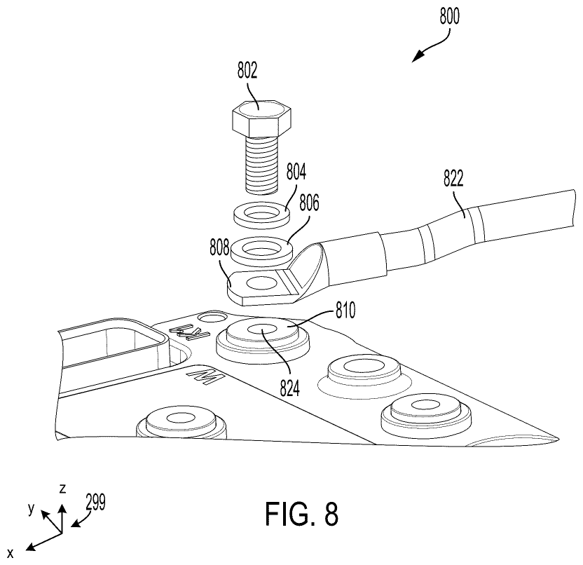

Once the air leakage test has been performed, the test channel in the power terminal may be sealed to prevent air leakage through the test channel. In one example, the test channel may be sealed via a bolt inserted into the power terminal threaded socket. A bolt may be used to couple a cable (or other electrical connector) to each power terminal of the inverter to external power sources or loads. An assembly that may be used to couple a cable to a power terminal via a bolt is shown in FIG. 8. FIG. 8 is a diagram showing an exploded view 800 of a cable 822 coupled to a power terminal 810. The cable 822 may have a lug head 808 that is placed on top of the power terminal 810. A washer 806 is placed atop the lug head, followed by an O-ring 804. A screw or bolt 802 may be placed through the O-ring 804, the washer 806, and the cable lug head 808 and screwed into a threaded socket 824 of the power terminal 810. Each power terminal of the inverter 600 of FIG. 6 may be coupled to an external power source or external load via a similar mechanism (e.g., a cable including a lug head may be coupled to a power terminal of FIG. 6 via a bolt as described above).

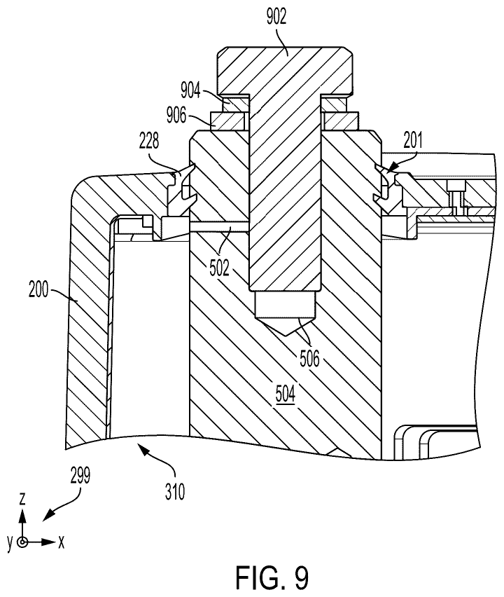

A cross sectional view of a bolt accommodated within a power terminal threaded socket is shown in FIG. 9. Specifically, FIG. 9 shows a bolt 902 that has been inserted into the second inner socket 506 in the power terminal 504. Washer 906 and O-ring 904 sit between the external surface of the power terminal 504 and the head of the bolt 902. The power terminal 504 sits within the first power terminal aperture 210 in the case 200, and it is encircled by the first power terminal seal 228. The test channel 502 is located in the side of the power terminal that connects the second inner socket 506 within the power terminal 504 with the interior space 310 within the case. In this case, the bolt 902 inserted into the second inner socket 506 blocks the test channel 502 from connecting to the second inner socket 506. This blockage prevents air from leaking out of the power terminal through the test channel once leak testing is concluded. The test channel 502 remains in the power terminal, but the end of the test channel that was previously in fluid contact with the second inner socket 506 is blocked by the bolt 902. This blockage ensures that there is no air flow from the interior of the case to the exterior of the case through the test channel 502 once testing is complete and the inverter is fully assembled. In some cases, thread locks, sealants, or glues may be applied around the bolt to further ensure ingress protection at the site of the test channel 502. A small rubber plug may also be inserted at the bottom of the second inner socket 506 to block the test channel 502. These methods ensure that air flow through the test channel 502 is prevented after testing.

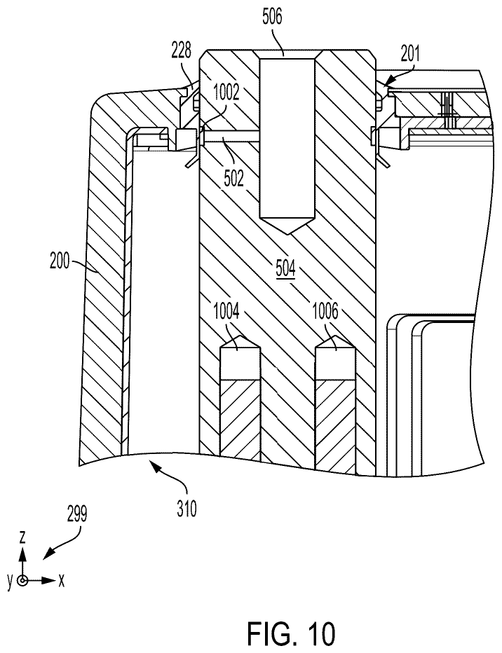

Another method for ingress protection at the site of the test channel is demonstrated in FIG. 10, which shows a cross sectional view of power terminal 504 extending through case 200. The power terminal 504 is encircled by the first power terminal seal 228. The power terminal 504 includes second inner socket 506 at the top in which a bolt or screw may be inserted and may include connectors to internal device electronics at the bottom, such as first connector 1004 and second connector 1006. Inside the power terminal 504 is the test channel 502 that connects the threaded socket within the power terminal to the interior space 310 of the case 200. A soft plastic valve 1002 may be realized with soft plastic injection to block the test channel 502 upon completion of the air leakage test. The test channel 502 remains inside of the power terminal after testing, but the valve 1002 prevents air exchange through The valve 1002 may prevent air exchange through the test channel 502 after testing, however, the test channel 502 may remain inside the power terminal.

When unblocked, the test channel 502 permits the exchange of air from the interior of the case to the environment, and can be used to facilitate an air leakage test. A method is disclosed herein to use a test channel within a power terminal, such as test channel 502, to test a device such as inverter for air leakage. In order to determine if a device is appropriately protected from the ingress of water and dust, the device may be tested to determine if air can escape from a case of the device. A previous method to accomplish this test involved an air compressor, a pressure reservoir housing with a pressure gauge, and a vacuum lid attached to a hose with a valve. The first step of this method involved filling the pressure reservoir housing with air from an air source to a pressure greater than the ambient pressure. The vacuum lid may be connected by the hose to the pressure housing. The vacuum lid may be affixed to a vent of the device, to form an airtight seal around the vent. The valve in the vacuum lid hose may allow air to flow from the pressure reservoir into the vacuum lid once the reservoir reaches a specific overpressure. Once air is allowed to flow from the reservoir to the interior of the device, the pressure inside the case and the reservoir may begin to equalize over time. Measuring the reservoir pressure once at the beginning of the equalization process and measuring again at a later time allows the airflow rate of through the vent to be verified. Measuring the reservoir pressure at a third, later time allows the air tightness of the case to be tested. If the pressure at the third time is equal to the equilibrium pressure, the case is airtight. If, however, the pressure at the third time is lower than the equilibrium pressure, the device case is leaking air.

The inventors have identified some drawbacks to this approach. This approach may require specialized equipment such as the vacuum lid and the reservoir, which can be bulky and incur additional manufacturing costs. Additionally, this approach can take several minutes to complete. This can cause significant manufacturing delays when manufacturing large numbers of cases. To overcome these drawbacks, the inventors have developed the method disclosed herein to test a device for air leakage. This method applies to the electronic devices that include power terminals, e.g., inverters. This method includes the manufacture of a pass-through hole (e.g., the test channel) within an inner threaded socket of a power terminal, that allows the interior of the device to be in fluid communication with inner threaded socket. An air compressor may be coupled with the threaded socket and pump air into the device through the pass-through hole to create an over pressure within the interior space of the device (e.g., within an interior space of a case of the device). Air may escape the case through a vent at a known rate. The rate of air escape through the vent can be determined by taking a first pressure measurement once the air compressor is shut off and a second air pressure measurement after a predetermined amount of time has passed since the air compressor was shut off. Comparing the difference in pressure between the two measurements to the expected pressure drop in a sealed case where air may only escape from the vent cap may allow manufacturers to diagnose housing leakages or blocked air vents in manufactured devices.

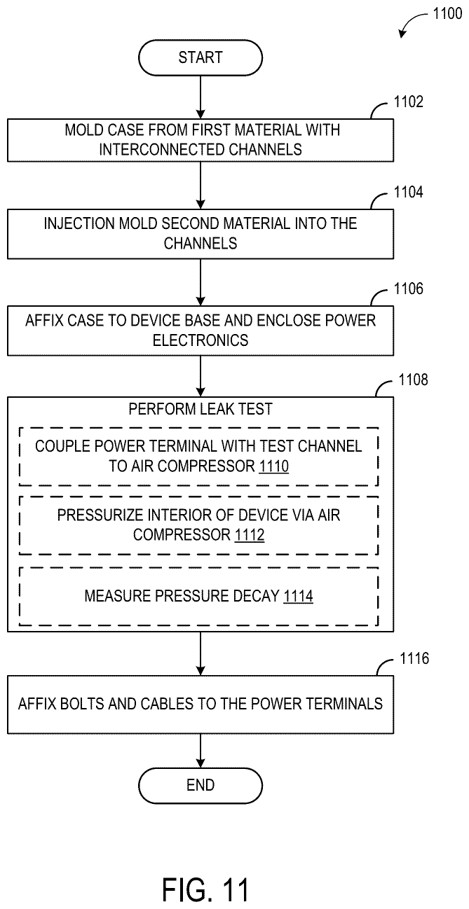

FIG. 11 is a flowchart that displays a method 1100 for manufacturing and testing power electronics device (e.g., an inverter) case. At 1102, method 1100 may include molding a case with a plurality of interconnected channels that connect a plurality of apertures for electronics and fastening devices. In some examples, the molding may include filling a hollow mold in the shape of a case with channels with a first material, such as a liquid form of a plastic that will solidify into a rigid material. Once the first material is hardened the molds can be removed, leaving a rigid plastic case (e.g., case 200) molded with interconnected channels and a plurality of apertures. At 1104, the method 1100 may include injection molding a second material into the plurality of interconnected channels. The injection molding may include placing molds over the case to form the shape of the power terminal seals and to confine the flow of the second material to the interconnected channels formed in the case. The second material may be a soft material, such as rubber or silicone, that may be injected into the cavity formed between the case and the molds. This soft material is capable of flowing through all of the channels as the channels are interconnected. When the soft material has hardened from a liquid to a solid form, seals are formed around the apertures of the case and in the channels. At 1106, the method includes affixing the case to a device base plate and enclosing power electronics. For example, the case may be positioned on the base plate so that all of the power terminals extend through the appropriate apertures in the case, and the bottom of the case is in face sharing contact with the base plate. The case may be affixed to the base plate with screws or other fasteners. It is to be appreciated that the power terminals may be positioned on the base plate prior to the case being positioned on the base plate, at least in some examples.

At 1108, the method 1100 may include performing an air leakage test on the assembled power electronics device to ensure the case protects the power electronics from the ingress of dust and water. The air leakage test may include coupling an air compressor to a power terminal of the power electronics device that includes a test channel at 1110. For example, a nozzle coupled to a hose coupled to the air compressor may be inserted into the inner threaded socket of the power terminal. The nozzle may be shaped to fit tightly to the threaded socket or include a seal to prevent the air exiting the nozzle from escaping into the environment. At 1112, the interior of the power electronics device may be pressurized via the air compressor. For example, the air compressor may be turned on and air may flow from the air compressor, through the hose and nozzle, through the threaded power terminal socket, and finally through the power terminal test channel and into the interior space of the power electronics device. The air compressor may be left on until an elevated threshold pressure has been reached within the interior of the power electronics device. At 1114, the method 1100 may include measuring the rate of pressure decay of the interior of the power electronics device. The air pressure within the case over time may be measured. If the case is sealed tightly, the air within the case may escape through a vent at a specific rate or, in the absence of a vent, the air pressure may remain stable. The rate at which air escapes the case may be used to determine if the case is fully sealed. At 1116, if the power electronics device is determined to be fully sealed, the method may include connecting the power electronics device to external sources and loads by affixing bolts and cables to the power terminals. This process is described in more detail with respect to FIG. 8, and may include inserting a bolt through a plurality of washers, a lug end of a cable, and into the power terminal threaded socket. The bolt may block the outlet of the test channel connected to the threaded power terminal socket. In this way, the test channel remains in the body of the power terminal but all airflow through the test channel is prevented. This ensures that the case is air tight after testing. If the power electronics device is determined not to be fully sealed, such as if the pressure decays at a faster rate than expected, the power electronics device may be inspected to determine the source of the leak, and if identified, the source of the leak may be sealed. In other examples, if the power electronics device is determined not to be fully sealed, the power electronics device may be discarded.

FIGS. 1-6 and 8-10 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Additionally, elements co-axial with one another may be referred to as such, in one example. Further, elements shown intersecting one another may be referred to as intersecting elements or intersecting one another, in at least one example. Further still, an element shown within another element or shown outside of another element may be referred as such, in one example. In other examples, elements offset from one another may be referred to as such.

The disclosure also provides support for a method for manufacturing a case for a power electronics device, the method comprising: molding the case using a first material, wherein the molding comprises molding a plurality of interconnected channels extending across a surface of the case and around a plurality of power terminal apertures of the case, and injecting a second material into the plurality of interconnected channels to form a continuous seal. In a first example of the method, the continuous seal includes a plurality of power terminal seals, each power terminal seal accommodated within a respective channel of the plurality of interconnected channels that extends around a respective power terminal aperture. In a second example of the method, optionally including the first example, the method further comprises: assembling the power electronics device by securing the case to a baseplate and positioning a plurality of power terminals in the case such that each power terminal aperture accommodates a respective power terminal of the plurality of power terminals. In a third example of the method, optionally including one or both of the first and second examples, the method further comprises: performing a leak test on the power electronics device by pumping air to an interior space of the power electronics device via a test channel formed in a power terminal of the plurality of power terminals, the test channel fluidly coupling the interior space to a socket of the power terminal. In a fourth example of the method, optionally including one or more or each of the first through third examples, performing the leak test further comprises, upon a pressure of the interior space reaching a threshold pressure, monitoring a rate of pressure decay of the interior space and determining a sealing state of the power electronics device based on the rate of pressure decay. In a fifth example of the method, optionally including one or more or each of the first through fourth examples responsive to determining that the sealing state of the power electronics device is fully sealed, sealing the test channel. In a sixth example of the method, optionally including one or more or each of the first through fifth examples, the first material comprises plastic. In a seventh example of the method, optionally including one or more or each of the first through sixth examples, the second material comprises rubber. In an eighth example of the method, optionally including one or more or each of the first through seventh examples, molding the plurality of interconnected channels further comprises molding a bottom sealing channel within a bottom circumferential edge of the case, and wherein injecting the second material into the plurality of interconnected channels to form the continuous seal comprises injecting the second material into the plurality of interconnected channels including the bottom sealing channel.

The disclosure also provides support for a case for a power electronics device, comprising: a top including a plurality of power terminal apertures, a plurality of sides, and a bottom circumferential edge configured to couple to a baseplate to enclose power electronics of the power electronics device, wherein an interior surface of the case includes a plurality of interconnected channels extending around the bottom circumferential edge, across the top and the plurality of sides, and around the plurality of power terminal apertures, and a continuous seal accommodated in the plurality of interconnected channels. In a first example of the system, the system further comprises: a power terminal extending through a power terminal aperture of the plurality of power terminal apertures. In a second example of the system, optionally including the first example, the power terminal includes a test channel fluidly coupling an inner socket of the power terminal to an interior space of the power electronics device. In a third example of the system, optionally including one or both of the first and second examples, the continuous seal includes a sealing gasket portion and a plurality of power terminal seals, the sealing gasket portion accommodated within the bottom circumferential edge of the case and each power terminal seal of the plurality of power terminal seals surrounding a respective power terminal aperture. In a fourth example of the system, optionally including one or more or each of the first through third examples, the continuous seal further includes a plurality of sealing segments coupling the plurality of power terminal seals to the sealing gasket portion and to each other. In a fifth example of the system, optionally including one or more or each of the first through fourth examples, a portion of the plurality of sealing segments extend along one or more sides of the plurality of sides of the case.

The disclosure also provides support for a system, comprising: a power electronics device, and a case coupled with the power electronics device, the case having a top including a plurality of power terminal apertures, a plurality of sides, and a bottom circumferential edge configured to couple to a baseplate to enclose power electronics of the power electronics device, wherein an interior surface of the case includes a plurality of interconnected channels extending around the bottom circumferential edge, across the top and the plurality of sides, and around the plurality of power terminal apertures, and a continuous seal accommodated in the plurality of interconnected channels, the continuous seal having a sealing gasket portion and a plurality of power terminal seals, the sealing gasket portion accommodated within the bottom circumferential edge of the case and each power terminal seal of the plurality of power terminal seals surrounding a respective power terminal aperture, the continuous seal including interior scalloping. In a first example of the system, each power terminal seal further includes a double-lip and wherein the continuous seal further includes a plurality of sealing segments coupling the plurality of power terminal seals to the sealing gasket portion and to each other. In a second example of the system, optionally including the first example, a portion of the plurality of sealing segments extend along one or more sides of the plurality of sides of the case. In a third example of the system, optionally including one or both of the first and second examples, the system further comprises: a power terminal extending through a power terminal aperture of the plurality of power terminal apertures. In a fourth example of the system, optionally including one or more or each of the first through third examples, the power terminal includes a test channel fluidly coupling an inner socket of the power terminal to an interior space of the power electronics device. In a fifth example of the system, optionally including one or more or each of the first through fourth examples, the interior scalloping of the continuous seal includes interior scalloping on one or more faces of each power terminal seal.

While various embodiments have been described above, it should be understood that they have been presented by way of example, and not limitation. It will be apparent to persons skilled in the relevant arts that the disclosed subject matter may be embodied in other specific forms without departing from the spirit of the subject matter. The embodiments described above are therefore to be considered in all respects as illustrative, not restrictive. As such, the configurations and routines disclosed herein are exemplary in nature, and that these specific examples are not to be considered in a limiting sense, because numerous variations are possible. For example, the above technology can be applied to a variety of electric systems. The subject matter of the present disclosure includes all novel and non-obvious combinations and sub-combinations of the various systems and configurations, and other features, functions, and/or properties disclosed herein.

As used herein, the term “approximately” is construed to mean plus or minus five percent of the range, unless otherwise specified.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A method for manufacturing a case for a power electronics device, the method comprising:
molding the case using a first material, wherein the molding comprises molding a plurality of interconnected channels extending across a surface of the case and around a plurality of power terminal apertures of the case; and
injecting a second material into the plurality of interconnected channels to form a continuous seal.

2. The method of claim 1, wherein the continuous seal includes a plurality of power terminal seals, each power terminal seal accommodated within a respective channel of the plurality of interconnected channels that extends around a respective power terminal aperture.

3. The method of claim 2, further comprising assembling the power electronics device by securing the case to a baseplate and positioning a plurality of power terminals in the case such that each power terminal aperture accommodates a respective power terminal of the plurality of power terminals.

4. The method of claim 3, further comprising performing a leak test on the power electronics device by pumping air to an interior space of the power electronics device via a test channel formed in a power terminal of the plurality of power terminals, the test channel fluidly coupling the interior space to a socket of the power terminal.

5. The method of claim 4, wherein performing the leak test further comprises, upon a pressure of the interior space reaching a threshold pressure, monitoring a rate of pressure decay of the interior space and determining a sealing state of the power electronics device based on the rate of pressure decay.

6. The method of claim 5, responsive to determining that the sealing state of the power electronics device is fully sealed, sealing the test channel.

7. The method of claim 1, wherein the first material comprises plastic.

8. The method of claim 1, wherein the second material comprises rubber.

9. The method of claim 1, wherein molding the plurality of interconnected channels further comprises molding a bottom sealing channel within a bottom circumferential edge of the case, and wherein injecting the second material into the plurality of interconnected channels to form the continuous seal comprises injecting the second material into the plurality of interconnected channels including the bottom sealing channel.

10. A case for a power electronics device, comprising:
a top including a plurality of power terminal apertures, a plurality of sides, and a bottom circumferential edge configured to couple to a baseplate to enclose power electronics of the power electronics device, wherein an interior surface of the case includes a plurality of interconnected channels extending around the bottom circumferential edge, across the top and the plurality of sides, and around the plurality of power terminal apertures; and
a continuous seal accommodated in the plurality of interconnected channels.

11. The case of claim 10, further comprising a power terminal extending through a power terminal aperture of the plurality of power terminal apertures.

12. The case of claim 11, wherein the power terminal includes a test channel fluidly coupling an inner socket of the power terminal to an interior space of the power electronics device.

13. The case of claim 10, wherein the continuous seal includes a sealing gasket portion and a plurality of power terminal seals, the sealing gasket portion accommodated within the bottom circumferential edge of the case and each power terminal seal of the plurality of power terminal seals surrounding a respective power terminal aperture.

14. The case of claim 13, wherein the continuous seal further includes a plurality of sealing segments coupling the plurality of power terminal seals to the sealing gasket portion and to each other.

15. The case of claim 14, wherein a portion of the plurality of sealing segments extend along one or more sides of the plurality of sides of the case.

16. A system, comprising:
a power electronics device; and
a case coupled with the power electronics device, the case having a top including a plurality of power terminal apertures, a plurality of sides, and a bottom circumferential edge configured to couple to a baseplate to enclose power electronics of the power electronics device, wherein an interior surface of the case includes a plurality of interconnected channels extending around the bottom circumferential edge, across the top and the plurality of sides, and around the plurality of power terminal apertures; and
a continuous seal accommodated in the plurality of interconnected channels, the continuous seal having a sealing gasket portion and a plurality of power terminal seals, the sealing gasket portion accommodated within the bottom circumferential edge of the case and each power terminal seal of the plurality of power terminal seals surrounding a respective power terminal aperture, the continuous seal including interior scalloping.

17. The system of claim 16, wherein each power terminal seal includes a double-lip and wherein the continuous seal further includes a plurality of sealing segments coupling the plurality of power terminal seals to the sealing gasket portion and to each other.

18. The system of claim 17, wherein a portion of the plurality of sealing segments extend along one or more sides of the plurality of sides of the case.

19. The system of claim 17, further comprising a power terminal extending through a power terminal aperture of the plurality of power terminal apertures.

20. The system of claim 19, wherein the power terminal includes a test channel fluidly coupling an inner socket of the power terminal to an interior space of the power electronics device.
